(19) United States
(12) Patent Application Publication
(10) Pub. No.: US 2026/0299397 A1
(43) Pub. Date: Oct. 1, 2026

(54) EUV MASK REGISTRATION CONTROL METHOD AND EUV MASK MANUFACTURING METHOD INCLUDING THE CONTROL METHOD

(71) Applicant: Samsung Electronics Co., Ltd., Suwon-si (KR)

(72) Inventors: Myoungsoo Lee, Suwon-si (KR); Changsu Park, Suwon-si (KR)

(21) Appl. No.: 19/389,842

(22) Filed: Nov. 14, 2025

(30) Foreign Application Priority Data
Mar. 27, 2025 (KR) 10-2025-0039806

(51) Int. Cl. G03F 1/24; G03F 1/54; G03F 1/86

(52) U.S. Cl. CPC G03F 1/24; G03F 1/54; G03F 1/86

(57) ABSTRACT

A registration control method includes irradiating a laser beam or an E-beam onto a reflective multilayer of an EUV mask, the EUV mask having a substrate, the reflective multilayer on the substrate, and an absorption layer on the reflective multilayer, generating an asymmetrical deformation element in the reflective multilayer, and correcting the registration of a pattern formed on the absorption layer.

### CROSS-REFERENCE TO RELATED APPLICATION

This application is based on and claims priority under 35 U.S.C. §119 to Korean Patent Application No. 10-2025-0039806, filed on Mar. 27, 2025, in the Korean Intellectual Property Office, the disclosure of which is incorporated by reference herein in its entirety.

### BACKGROUND

To meet the demands for the excellent performance and low price demanded by consumers, the size of patterns formed on a semiconductor substrate is becoming smaller and smaller. In addition, to meet the technical requirements for smaller sizes of patterns formed on the semiconductor substrate, the wavelength of a light source used in the lithography process is becoming shorter and shorter.

### SUMMARY

In related art, the lithography process has used g-line (436 nm) and i-line (365 nm) and has used light in the deep ultraviolet (DUV) band and the extreme ultraviolet (EUV) band. Patterns on a mask may be transferred to a wafer through an exposure process. However, the patterns on the mask may exhibit registration errors due to changes in the spacing and directionality between the patterns during a manufacturing process.

Implementations according to the present disclosure provide a method of controlling registration of an extreme ultra-violet (EUV) mask which may correct an error in registration of a pattern on an EUV mask, and a method of manufacturing an EUV mask including the control method.

The problems to be solved by implementations of the present disclosure are not limited to the problems mentioned above, and other problems not mentioned will be clearly understood by those skilled in the art from the following description.

An aspect of the present disclosure provides a method of controlling registration of an extreme ultra-violet (EUV) mask. The method includes irradiating a laser beam or an E-beam onto a reflective multilayer of the EUV mask including a substrate, the reflective multilayer on the substrate, and an absorption layer on the reflective multilayer, generating an asymmetric deformation element in the reflective multilayer, and correcting the registration of a pattern formed in the absorption layer.

Another aspect of the present disclosure provides a method of controlling registration of an extreme ultra-violet (EUV) mask. The method includes inspecting registration of a pattern of an absorption layer of the EUV mask including a substrate, a reflective multilayer on the substrate, and the absorption layer on the reflective multilayer, irradiating a laser beam or an E-beam onto the reflective multilayer through the substrate from a rear surface of the EUV mask, generating an asymmetric deformation element in the reflective multilayer, and correcting the registration. Irradiating the laser beam or the E-beam includes asymmetrically deforming an intensity distribution on a plane of the laser beam or asymmetrically deforming the energy distribution on a plane of the E- beam.

Another aspect of the present disclosure provides a method of controlling registration of an extreme ultra-violet (EUV) mask. The method includes preparing an EUV blank mask including a substrate, a reflective multilayer on the substrate, and an absorption layer on the reflective multilayer, forming a pattern in the absorption layer of the EUV blank mask, and controlling registration of the pattern. Controlling the registration includes irradiating a laser beam or an E-beam onto the reflective multilayer, generating an asymmetric deformation element in the reflective multilayer, and correcting the registration.

### BRIEF DESCRIPTION OF THE DRAWINGS

FIG. 1 is a flowchart schematically showing an example method of controlling registration of an extreme ultra-violet (EUV) mask.

FIGS. 2A and 2B are respectively a plan view and a cross-sectional view of an example of an EUV mask.

FIGS. 3A-3C are conceptual diagrams showing the principle of controlling registration of a pattern on an example of an EUV mask.

FIG. 4 is a graph showing depth shrinkage and registration change according to the energy of a laser beam applied to a reflective multilayer of an example of an EUV mask.

FIGS. 5A and 5B are photographs showing changes in a reflective multilayer when a laser beam is irradiated on the reflective multilayer of an example of an EUV mask, and FIG. 5C is a graph showing conditional depth shrinkage according to the energy of the laser beam.

FIG. 6 is a conceptual diagram showing the asymmetrical intensity of a laser beam and the registration change according to the asymmetrical shape of the laser beam.

FIGS. 7A-8B are conceptual diagrams showing example methods of forming an asymmetrical shape of a laser beam and registration change according to the asymmetrical shape.

FIG. 9 is a conceptual diagram for distinguishing asymmetric deformation elements through aspect ratio.

FIGS. 10A and 10B are respectively a plan view and an enlarged view of an example of an EUV mask.

FIG. 11 is a conceptual diagram showing the principle of an example method of controlling registration of an example of an EUV mask.

FIG. 12 is a flowchart schematically showing an example method of manufacturing an example of an EUV mask, including an example method of controlling registration of an EUV mask.

### DETAILED DESCRIPTION

Hereinafter, implementations of the present disclosure will be described in detail with reference to the accompanying drawings. Like reference numerals are used for elements that are substantially identical to each other, and the descriptions thereof will not be repeated.

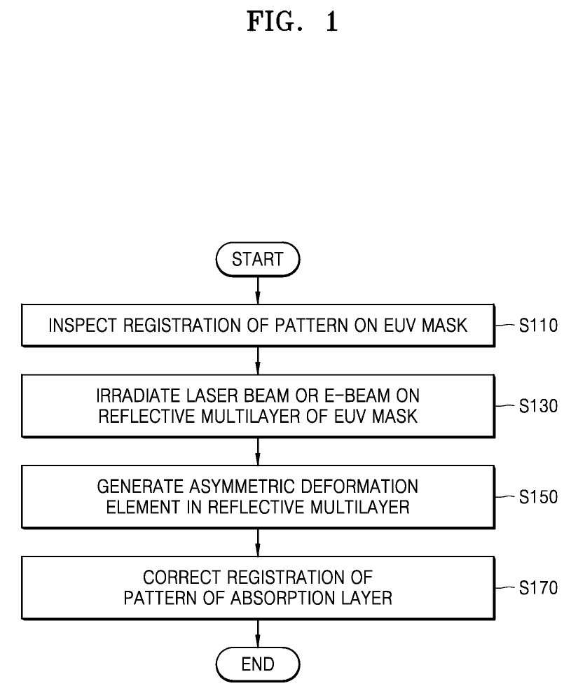

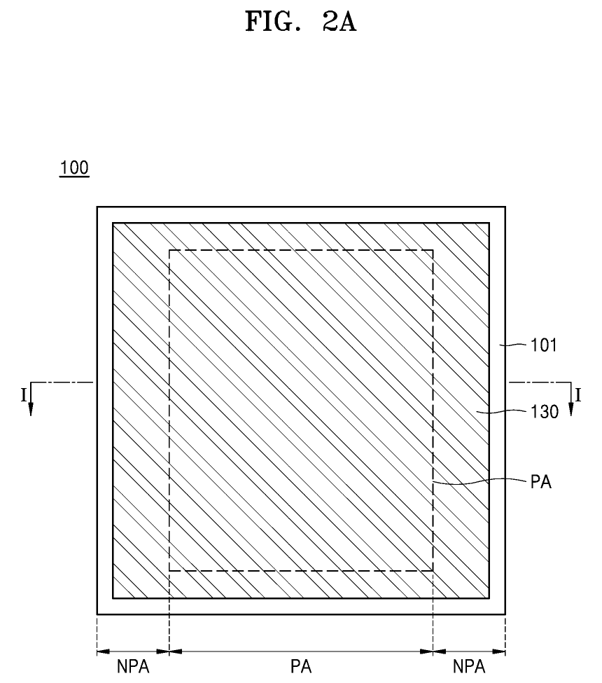

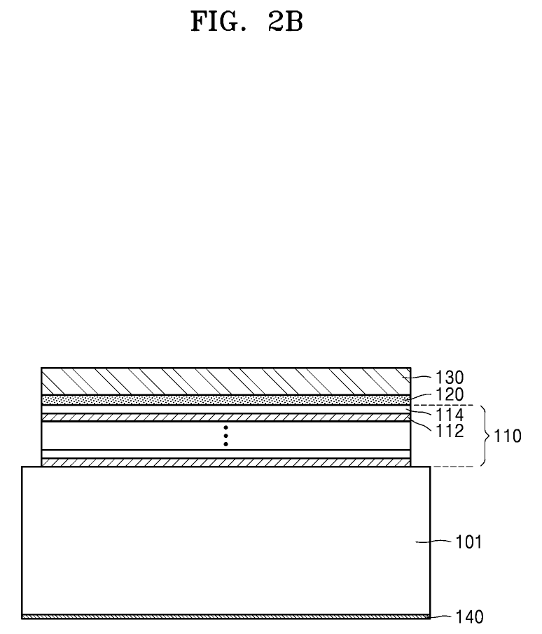

FIG. 1 is a flowchart schematically showing a method of controlling registration of an EUV mask, according to some implementations. FIGS. 2A and 2B are respectively a plan view and a cross-sectional view of an extreme ultra-violet (EUV) mask 100, and FIG. 2B is a cross-sectional view taken along line I-I’ of FIG. 2A.

Referring to FIGS. 1-2B, an example registration control method of the EUV mask 100 of the present disclosure (hereinafter, simply referred to as the “registration control method) first inspects the registration of a pattern on the EUV mask 100 (S110). The inspection of the registration of the pattern may refer to a process of inspecting the degree of deviation of the pattern on the EUV mask 100 from the design pattern position, that is, the registration error of the pattern. A registration map of the EUV mask 100 may be generated through the registration inspection of the pattern. Here, the registration map may refer to a map that displays the registration errors for the patterns in the form of a vector. For example, in the registration map, the degree of deviation of the patterns from the normal position may be indicated by a direction and size of an arrow. Hereinafter, for convenience of expression, “registration of pattern” is simply referred to as “registration,” except in cases where it is necessary. In addition, because registration generally denotes registration error, “registration error” is also simply referred to as “registration,” except in cases where it is necessary.

With reference to FIGS. 2A and 2B, the structure of the EUV mask 100 will be briefly described. The EUV mask 100 may include a substrate 101, a reflective multilayer 110, a capping layer 120, an absorption layer 130, and a rear conductive layer 140. As may be seen from FIG. 2A, in some examples, the substrate 101, the reflective multilayer 110, the capping layer 120, and the absorption layer 130 may have a rectangular shape in terms of plane. Also, in some examples, the reflective multilayer 110, the capping layer 120, and the absorption layer 130 may have substantially the same size. However, in some implementations, the reflective multilayer 110, the capping layer 120, and the absorption layer 130 may have different sizes from each other.

The substrate 101 may have the largest size. Accordingly, the substrate 101 may have an upper surface exposed in a rectangular frame shape at an outer portion. The substrate 101 may include a low thermal expansion material (LTEM) material. In other words, the substrate 101 may include a material having a low coefficient of thermal expansion (CTE). In some examples, the substrate 101 may include glass, silicon (Si), quartz, etc. In some implementations, the substrate 101 may be made of other materials.

A transfer area PA and a non-transfer area NPA may be defined on the substrate 101. As shown in FIG. 2A, the transfer area PA may be arranged in a central area, and the non-transfer area NPA may be arranged in a form surrounding the transfer area PA. Here, the transfer area PA may denote an area where patterns to be transferred onto a wafer are arranged through an exposure process. The patterns to be transferred onto the wafer may be formed on the absorption layer 130. Corresponding to the definition of the transfer area PA and the non-transfer area NPA of the substrate 101, the absorption layer 130 may also be distinguished into the transfer area PA and the non-transfer area NPA. Therefore, the patterns to be transferred onto the wafer may be arranged on the transfer area PA of the absorption layer 130.

The reflective multilayer 110 may be arranged on the substrate 101. The reflective multilayer 110 may reflect light, for example, EUV light (ray) incident on the reflective multilayer 110. For example, the reflective multilayer 110 may correspond to a Bragg reflector. In the EUV mask 100, the reflective multilayer 110 may have a multilayer structure in which two material layers are alternately stacked in dozens of layers. That is, the reflective multilayer 110 may include a first material layer 112 and a second material layer 114 that are alternately stacked. In the EUV mask 100, the pair of the first material layer 112 and the second material layer 114 may be stacked in about 40 layers to about 60 layers. In some implementations, there may be less than 40 layers or greater than 60 layers.

Here, the first material layer 112 may be a low refractive index layer, and the second material layer 114 may be a high refractive index layer. Therefore, the second material layer 114 may have a higher refractive index than the first material layer 112. For example, the first material layer 112 may include molybdenum (Mo), and the second material layer 114 may include Si. In some implementations, the first material layer 112 and the second material layer 114 may include or be composed of materials other than Mo and Si. Meanwhile, in the EUV mask 100, the first material layer 112, which is a low refractive index layer, may be arranged at the bottom of the reflective multilayer 110, and the second material layer 114, which is a high refractive index layer, may be arranged at the top of the reflective multilayer 110.

The capping layer 120 may be arranged on the reflective multilayer 110. The capping layer 120 may prevent damage to the reflective multilayer 110 and surface oxidation of the reflective multilayer 110. In the EUV mask 100, the capping layer 120 may cover an upper surface of the second material layer 114 of, for example, Si, to prevent the second material layer 114 from being oxidized. For example, the capping layer 120 may include ruthenium (Ru). In some implementations, the capping layer 120 may include or be composed of a material other than Ru. In some examples, the capping layer 120 may be optional. Accordingly, in some examples, the capping layer 120 may be omitted.

The absorption layer 130 may be disposed on the capping layer 120. If the capping layer 120 is omitted, the absorption layer 130 may be disposed directly on the reflective multilayer 110, for example, the second material layer 114. The absorption layer 130 may be divided into a central transfer area PA and an outer non-transfer area NPA. In the transfer area PA, patterns to be transferred onto the wafer through an exposure process may be disposed.

Here, the EUV mask 100 may be an EUV completion mask. The EUV completion mask may denote an EUV mask in which a pattern is formed on the absorption layer 130. An EUV blank mask, which is a relative concept to the EUV completion mask, may denote an EUV mask before a pattern is formed on the absorption layer 130.

The absorption layer 130 may include a material that absorbs light incident on the absorption layer 130, for example, EUV light. Therefore, EUV light incident on the absorption layer 130 may not reach the capping layer 120 or the reflective multilayer 110. The absorption layer 130 may include, for example, TaN, TaHf, TaHfN, TaBSi, TaBSiN, TaB, TaBN, TaSi, TaSiN, TaGe, TaGeN, TaZr, TaZrN, or any combination thereof. In some implementations, the absorption layer 130 may include or be composed of other materials.

EUV light incident on the capping layer 120 exposed through an open area of the absorption layer 130 may penetrate the capping layer 120 and reach the reflective multilayer 110. In addition, the EUV light may be reflected by the reflective multilayer 110 and irradiated onto the wafer as an exposure target. Therefore, the pattern transferred onto the wafer may correspond to the shape of the open area of the absorption layer 130.

The rear conductive layer 140 may be formed on a lower surface of the substrate 101. The rear conductive layer 140 may be formed to attach the EUV mask 100 to the mask stage through electrostatic force. Therefore, the rear conductive layer 140 can include a conductive material such as a metal. For example, the rear conductive layer 140 may be formed by coating a conductive material, chromium nitride (CrN), on the lower surface of the substrate 101. In some implementations, the rear conductive layer 140 may include or be composed of a material other than CrN.

After the registration inspection of the pattern, a laser beam or an E-beam is irradiated to the reflective multilayer 110 of the EUV mask 100 (S130). The laser beam or the E-beam may apply energy to the reflective multilayer 110 in shot units. In some implementations, in the operation of irradiating the laser beam or the E-beam (S130), energy may be applied to the reflective multilayer 110 by irradiating a different type of beam instead of the laser beam or the E-beam.

Through the irradiation of the laser beam or the E-beam, an asymmetric deformation element (ADE) is generated in the reflective multilayer 110 of the EUV mask 100 (S150). More specifically, when a laser beam or an E-beam is irradiated on the reflective multilayer 110 of the EUV mask 100, a depth shrinkage of the reflective multilayer 110 may occur due to diffusion of intermixing between the first material layer 112 and the second material layer 114 and formation of silicide within the reflective multilayer 110. Compressive stress may act on the absorption layer 130 due to the depth shrinkage. Therefore, by utilizing this phenomenon, through controlling the shape of the laser beam or controlling the distribution of the E-beam, an ADE may be generated in the horizontal or vertical direction in the reflective multilayer 110, and through this, the registration may be corrected to improve the quality of the EUV mask. Here, the horizontal or vertical direction may denote an X-axis direction or a Y-axis direction on the X-Y plane.

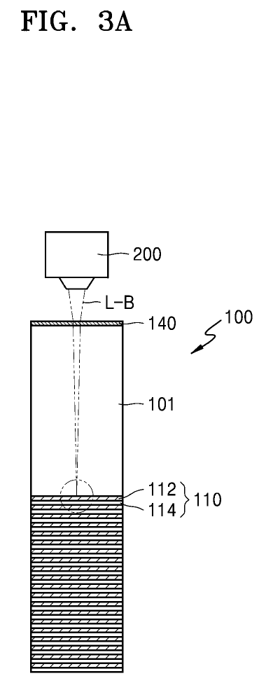

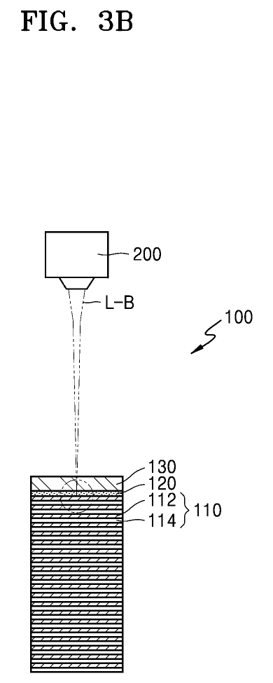

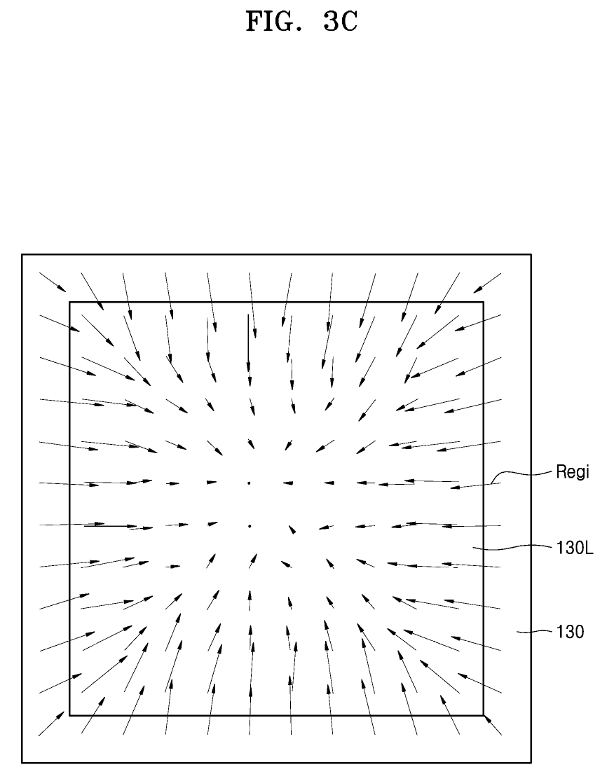

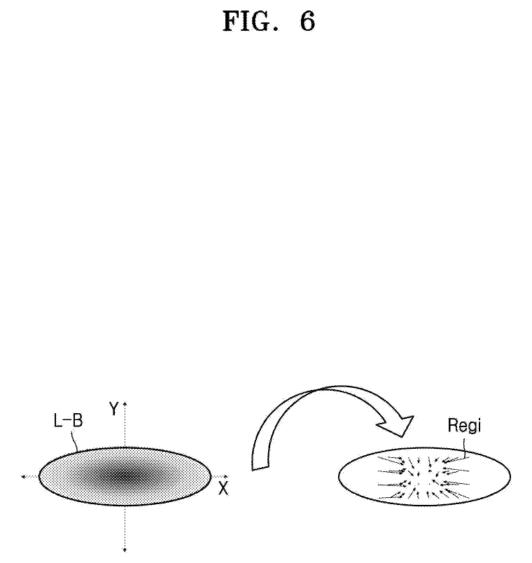

The depth shrinkage of the reflective multilayer 110 and the change in registration by irradiation with the laser beam or E-beam are described in more detail in the description of FIGS. 3A-5C. In addition, the shape control of the laser beam or the distribution control of the E-beam, the change in registration, the formation of the asymmetric deformation element, the correction of registration, etc. are described in more detail in the description of FIGS. 6-11.

The registration of the pattern of the absorption layer 130 is corrected by forming an ADE (S170). In other words, as the ADE is formed in the reflective multilayer 110, the pattern of the absorption layer 130 is subjected to compressive stress, causing movement, so that the registration error may be corrected.

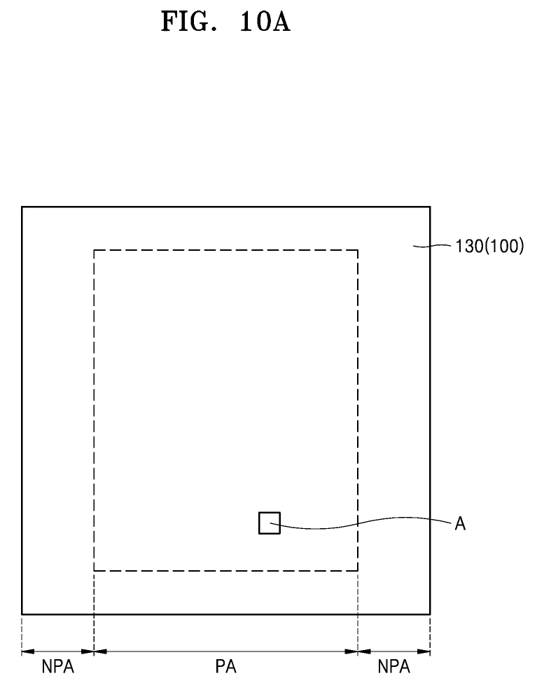

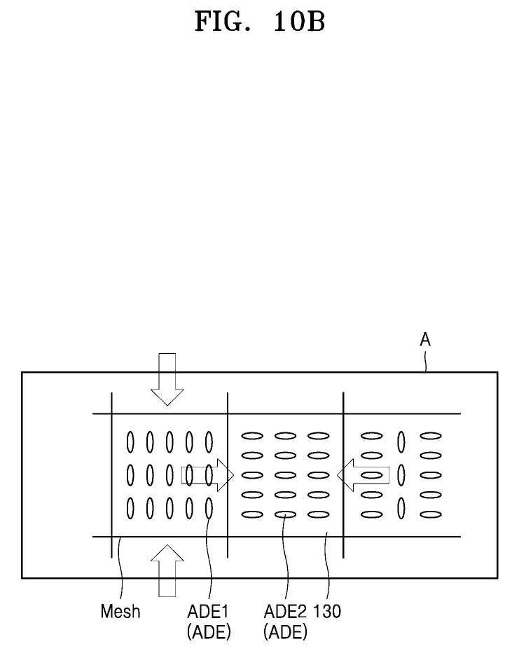

In the registration control method of the EUV mask according to some implementations, a laser beam or an E-beam may be applied to the reflective multilayer 110 by passing the substrate 101 through the rear surface of the EUV mask 100. In this way, an ADE may be generated in the reflective multilayer 110 by applying a laser beam or an E-beam, and the registration error of the pattern may be corrected by applying a compressive stress to the pattern of the absorption layer 130 through such an asymmetric deformation element, thereby improving the registration quality of the EUV mask. In addition, in the registration control method according to some implementations, as the laser beam or E-beam is applied to the reflective multilayer 110, the shot size of the laser beam or E-beam or a pitch between shots may be minimized to minimize the size of the ADE. Accordingly, by reducing the correction resolution and precisely correcting the registration error of the pattern, an excellent EUV mask with significantly improved registration quality may be manufactured. The correction resolution will be described in more detail in the description of FIGS. 10A and 10B.

Hereinafter, for the convenience of explanation, the energy application to the reflective multilayer 110 through irradiation of a laser beam will be described. In some implementations, same content may be applied to an E-beam.

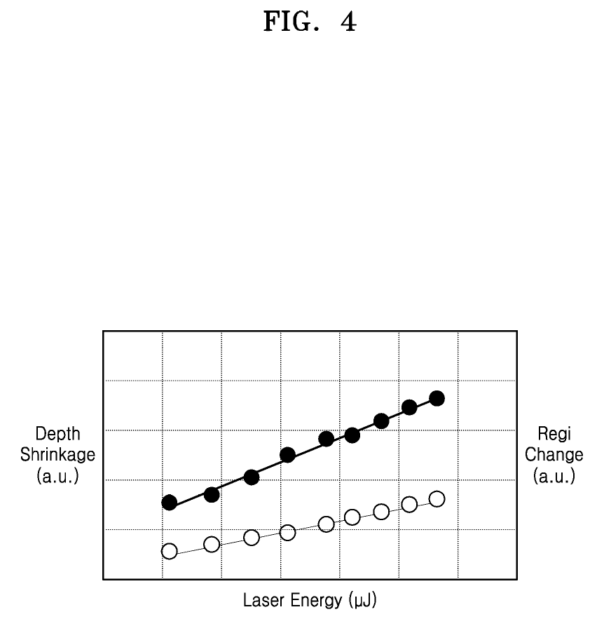

FIGS. 3A-3C are conceptual diagrams showing the principle of controlling registration of a pattern on an EUV mask, and FIG. 4 is a graph showing depth shrinkage and registration change according to the energy of a laser beam applied to a reflective multilayer of an EUV mask. In FIG. 4, the X-axis represents the energy applied through the laser beam, and the unit is microjoule (μJ), and the Y-axis represents depth shrinkage of the reflective multilayer and change in registration of the pattern, and both units are arbitrary units.

Referring to FIGS. 3A-3C, FIG. 3A shows a process of irradiating a laser beam L-B from a laser device 200 onto the reflective multilayer 110 of the EUV mask 100 from the rear side. The EUV mask 100 of FIG. 3A may correspond to the case in which the EUV mask 100 of FIG. 2B is flipped upside down. Only a part of the rear conductive layer 140, the substrate 101, and the reflective multilayer 110 are shown. The laser beam L-B may be irradiated from a rear side of the rear conductive layer 140 and penetrate the rear conductive layer 140 and the substrate 101 to be irradiated to the reflective multilayer 110. With reference to the EUV mask 100 of FIG. 2B, the laser beam L-B may be irradiated to a lower layer of the reflective multilayer 110.

FIG. 3B shows a process of irradiating the laser beam L-B from the front side onto the reflective multilayer 110 of the EUV mask 100 in the laser device 200. The EUV mask 100 of FIG. 3B may have the same structure as the EUV mask of FIG. 2B. A part of the reflective multilayer 110, the capping layer 120, and the absorption layer 130 are illustrated. The laser beam L-B may be irradiated from the side of the absorption layer 130 and may irradiate to the reflective multilayer 110 by penetrating the absorption layer 130 and the capping layer 120, or the capping layer 120. In some examples, if the capping layer 120 is omitted, the laser beam L-B may penetrate the absorption layer 130 and irradiate to the reflective multilayer 110 or may be irradiated directly to the reflective multilayer 110.

FIG. 3C may correspond to a registration map showing the change in registration of the absorption layer 130 when the laser beam L-B is irradiated to the central portion of the reflective multilayer 110 on an X-Y plane. The registration map may have a square shape on the X-Y plane corresponding to the horizontal cross section of the absorption layer 130. In FIG. 3C, an outer square may correspond to the horizontal cross-section of the absorption layer 130. Depending on some implementations, the outer square may correspond to the horizontal cross-section of the EUV mask 100. An inner square may correspond to an area where the laser beam L-B is irradiated. In addition, the inner square may correspond to the transfer area PA. A plurality of arrows may represent registration Regi. That is, the arrows may represent the direction and size of the pattern movement. As the laser beam L-B is irradiated to the central portion of the X-Y plane of the reflective multilayer 110, in the registration map, the registration Regi may appear in a somewhat point-symmetrical form based on the center.

Referring to FIG. 4, it may be seen that as more energy is applied through the laser beam L-B, the depth shrinkage of the reflective multilayer 110 increases, and also the change in registration increases. For reference, the depth shrinkage of the reflective multilayer 110 denotes that the depth of the reflective multilayer 110 decreases when viewed from the absorption layer 130, and may correspond to the substantially same meaning as the thickness shrinkage of the reflective multilayer 110.

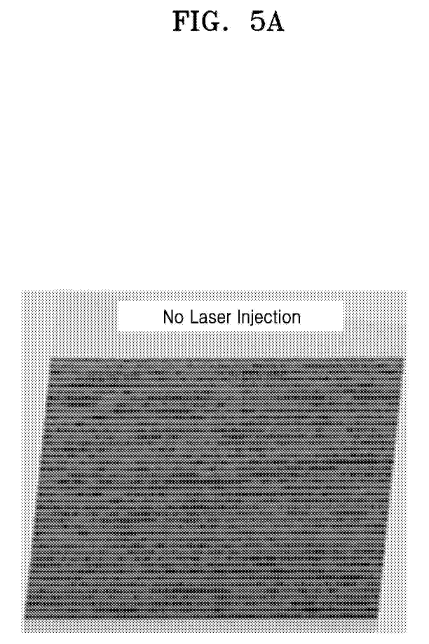

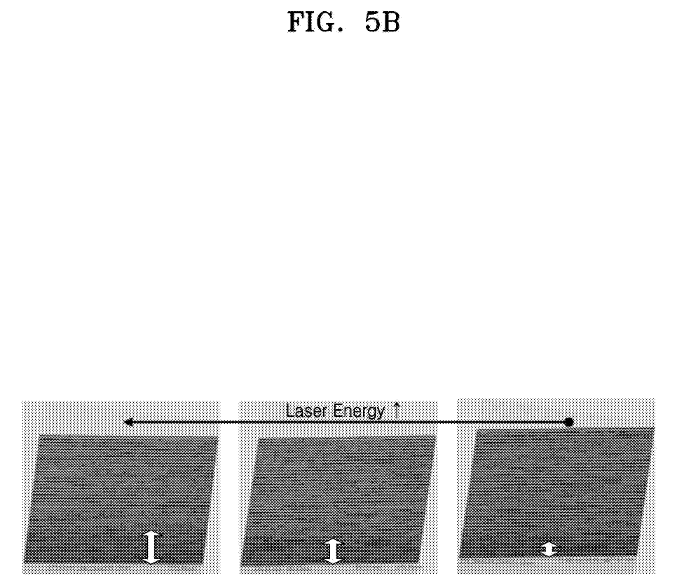

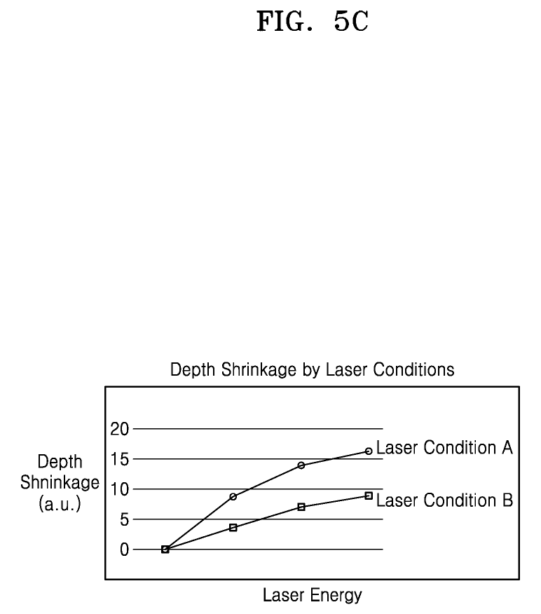

FIGS. 5A and 5B are photographs showing the change in the reflective multilayer when a laser beam is irradiated on the reflective multilayer of the EUV mask, and FIG. 5C is a graph showing the depth shrinkage according to conditions according to the energy of the laser beam. In FIG. 5C, the x-axis represents the energy applied through the laser beam and has no unit, and the y-axis represents the depth shrinkage of the reflective multilayer and the unit is an arbitrary unit. In addition, a laser condition A and a laser condition B are conditions for a size of an area to which the laser beam is irradiated, and the area to which the laser beam is irradiated under the laser condition A may be wider than that under the laser condition B. This will be explained with reference to FIGS. 2A and 2B together.

Referring to FIGS. 5A-5C, FIG. 5A shows the state of the reflective multilayer 110 that is not injected with the laser beam L-B, and FIG. 5B shows the state of the reflective multilayer 110 that is injected with the laser beam L-B with different energies. For example, in FIG. 5B, the energy of the injected laser beam L-B may increase from the right to the left. In the case of FIG. 5A, the reflective multilayer 110 shows a uniform state in all layers. However, in the case of FIG. 5B, it may be seen that depth shrinkage occurs in the lower part of the reflective multilayer 110 irradiated with the laser beam L-B through diffusion of mixing and formation of silicide. In addition, it may be seen that the greater the energy of the laser beam L-B, the deeper the depth shrinkage occurs in the reflective multilayer 110. Therefore, the greater the energy of the laser beam L-B, the greater the stress due to depth shrinkage, and also the greater the change in registration. Meanwhile, the laser conditions A and the laser conditions B may be states of the laser beam. For example, the state of the laser beam may include polarization, single mode and burst mode, types of oscillation modes, pulse mode and continuous wave mode, pulse widths, beam shapes, etc. Due to these states of the laser beam, when the energy is well absorbed by the reflective multilayer 110, and the diffusion of mixing and the formation of silicide are promoted, the depth shrinkage of the reflective multilayer 110 may increase.

As may be seen from the graph of FIG. 5C, the greater the energy applied through the laser beam, the greater the depth shrinkage of the reflective multilayer 110. In addition, the wider the area the laser beam is applied to, the faster the increase in depth shrinkage due to energy.

FIG. 6 is a conceptual diagram showing the asymmetrical intensity of a laser beam and the registration change according to the asymmetrical shape of the laser beam. The left side of FIG. 6 shows the shape of the laser beam on the X-Y plane as an intensity, and the darker the black color, the higher the intensity of the laser beam. The right side of FIG. 6 may correspond to a registration map showing the change in registration that may occur when the shape of the laser beam on the left is applied to the reflective multilayer 110. This will be explained with reference to FIGS. 2A and 2B together.

Referring to FIG. 6, in the shape of the laser beam on the left, the laser beam L-B may have an elliptical shape with the X-axis as the major axis on the X-Y plane. When this type of laser beam L-B is applied to the reflective multilayer 110, as may be seen from the right registration map, a large change in the registration Regi occurs in the X-axis direction. In other words, the arrows indicating the change in the registration Regi appear long in the X-axis direction and relatively short in the Y-axis direction. As a result, it may be seen that the direction of the registration Regi may be controlled by controlling the shape of the laser beam L-B.

Hereinafter, a part of the reflective multilayer 110 that causes the registration Regi to change in response to the asymmetric shape of the laser beam L-B is called an “asymmetric deformation element.” When the asymmetric deformation element is described more clearly, the asymmetric deformation element may correspond to a horizontal area of the shot on the reflective multilayer 110 when the laser beam L-B is injected in shot units. Accordingly, the right side in FIG. 6 may correspond to the registration map of a part of the asymmetric deformation element. In addition, the asymmetric deformation element is a conceptual unit that distinguishes the change in registration that occurs in the absorption layer 130 due to the depth shrinkage of the reflective multilayer 110 and the stress that occurs accordingly by irradiating the laser beam L-B in shot units of the laser beam.

Here, asymmetry may denote asymmetry in the concept of point symmetry. Accordingly, symmetry may be maintained in the concept of line symmetry based on the X-axis or Y-axis. Hereinafter, asymmetry may be used as the same concept.

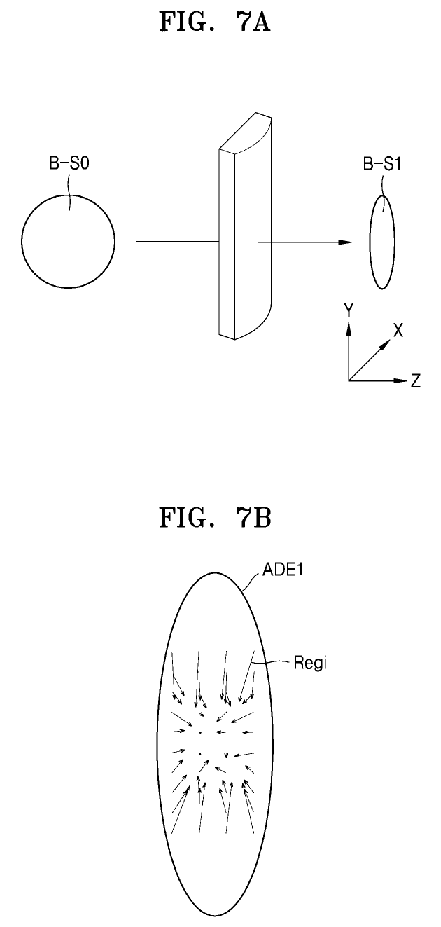

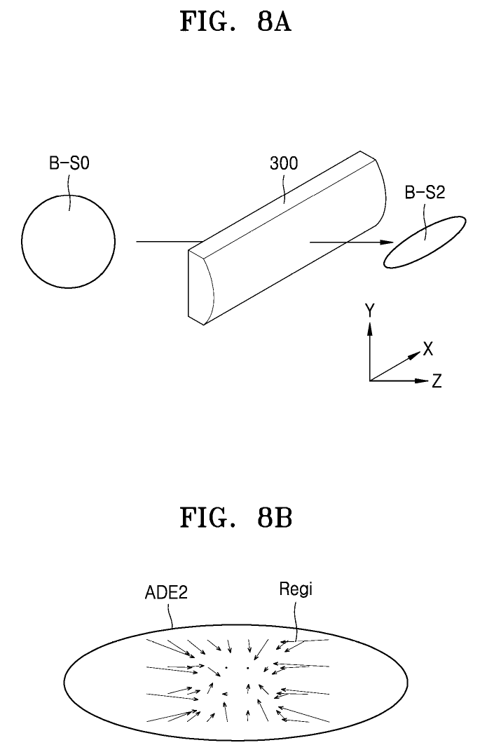

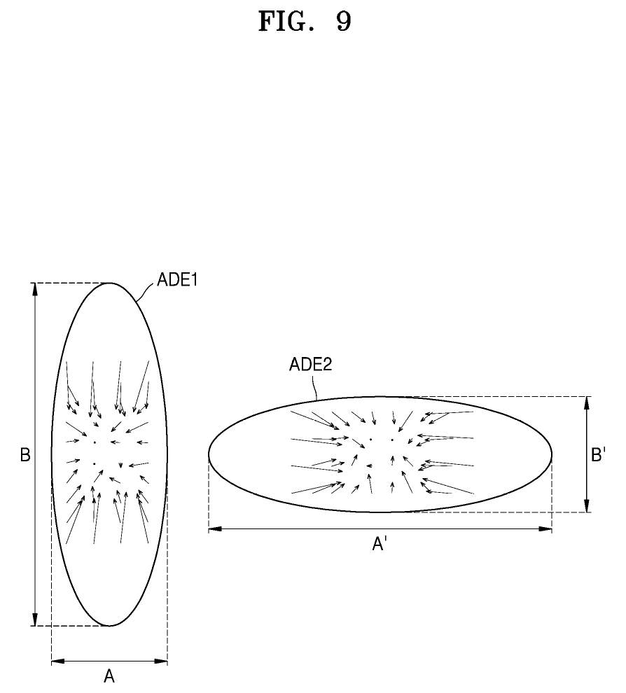

FIGS. 7A-8B are conceptual diagrams showing methods of forming an asymmetrical shape of a laser beam and the registration change according to the method, and FIG. 9 is a conceptual diagram distinguishing asymmetric deformation elements through an aspect ratio. It will be described with reference to FIGS. 1-3A together.

Referring to FIGS. 7A and 7B, in FIG. 7A, the left side is a horizontal cross-section of a laser beam L-B emitted from the laser device 200, which may represent an initial beam shape B-S0. The initial beam shape B-S0 may maintain symmetry as a circle. The initial beam shape B-S0 may be transformed into a first beam shape B-S1 while passing through a cylindrical lens 300. The first beam shape B-S1 may have an asymmetrical shape as an elliptical shape with the Y-axis as the major axis.

FIG. 7B shows a registration map of a first asymmetric deformation element ADE1 of the reflective multilayer 110 generated by the first beam shape B-S1. As may be seen from the registration map, it may be seen that the change in registration Regi in the Y-axis in the first asymmetric deformation element ADE1 is large in response to the first beam shape B-S1.

Referring to FIGS. 8A and 8B, in FIG. 8A, the left side is a horizontal cross-section of the laser beam L-B emitted from the laser device 200, which may represent the initial beam shape B-S0. The initial beam shape B-S0 may maintain symmetry as a circle. The initial beam shape B-S0 may be transformed into a second beam shape B-S2 while passing through a cylindrical lens 300a. Here, the cylindrical lens 300a may have a shape in which the cylindrical lens 300 of FIG. 7A is rotated 90° with respect to the optical axis along which the laser beam L-B travels, i.e., the Z-axis. In response to the shape of the cylindrical lens 300a, the second beam shape B-S2 may have an asymmetric shape as an elliptical shape with the X-axis as the major axis.

FIG. 8B shows a registration map of the second asymmetric deformation element ADE2 of the reflective multilayer 110 generated by the second beam shape B-S2. As may be seen from the registration map, there is a large change in registration Regi along the X-axis in the second asymmetric deformation element ADE2 corresponding to the second beam shape B-S2.

In FIGS. 7A and 8A, a method of generating an asymmetric deformation element by deforming the laser beam L-B into an asymmetrical shape through an optical component such as the cylindrical lens 300 or 300a is described. In some examples, the shape of the laser beam L-B may be deformed into an asymmetrical shape through a set of a wavefront sensor and a deformable mirror, spatial light modulators (SLM), hard aperture, etc. Here, the hard aperture may denote an optical element that deforms the shape of the laser beam L-B by controlling a physical shape of the aperture through which the laser beam L-B passes.

In addition, it may be possible to generate an asymmetric deformation element by deforming the intensity of the laser beam L-B asymmetrically through a change in the characteristics of the laser beam L-B. For example, an asymmetric deformation element may be generated by deforming the intensity of the laser beam L-B through laser polarization or laser oscillation mode.

The asymmetric deformation element may be arranged according to the position of the EUV mask 100 or the reflective multilayer 110 and the density of the asymmetric deformation element may be adjusted through a galvo scanner, an acousto-optic deflector (AOD), or stage movement. For example, the galvo scanner and the AOD may change a beam irradiation angle in a scan manner so that the laser beam L-B is irradiated according to the position of the reflective multilayer 110. On the other hand, in the case of stage movement, the laser beam L-B may be irradiated according to the position of the reflective multilayer 110 through the physical movement of the mask stage on which the EUV mask 100 is arranged.

So far, the laser beam has been described, but an asymmetric deformation element may also be generated through irradiation of an E-beam. In the case of an E-beam, an asymmetric deformation element may be generated by controlling the asymmetric distribution of the E-beam. For example, in the case of an E-beam, the distribution of the E-beam may be made asymmetrical through an electromagnetic element such as an electromagnetic lens, and accordingly, an asymmetric deformation element may be generated in the reflective multilayer 110.

Referring to FIG. 9, the first asymmetric deformation element ADE1 on the left of FIG. 9, may correspond to, for example, the first asymmetric deformation element ADE1 of FIG. 7B. In the aspect ratio based on the X-axis, an aspect ratio B/A of the first asymmetric deformation element ADE1 may be greater than 1. The first asymmetric deformation element ADE1 may correspond to a vertical deformation element. In the case of the vertical deformation element, the change in registration may be large in the Y-axis direction.

The second asymmetric deformation element ADE2 on the right may correspond to, for example, the second asymmetric deformation element ADE2 of FIG. 8B. An aspect ratio B'/A' of the second asymmetric deformation element ADE2 may be less than 1. The second asymmetric deformation element ADE2 may correspond to a horizontal deformation element. In the case of the horizontal deformation element, the change in registration may be large in the X-axis direction.

In addition, because a registration error is a placement in the X-axis direction and/or the Y-axis direction on an in-plane, an orthogonality set in the X-axis/Y-axis direction or the 45°/-45° direction may be required to correct and improve this. In advance, the vertical deformation element and the horizontal deformation element may form an orthogonal set in the X-axis/Y-axis direction. If an orthogonal set in the 45°/-45° direction is required, the orthogonal set in the 45°/-45° direction may be implemented by adjusting the rotation angle of the cylindrical lens in the 45°/-45° direction. Using the orthogonal set, the registration map of the EUV mask 100 may be used as input data, and the density of the asymmetric deformation elements according to the position in the EUV mask 100 may be controlled, thereby controlling and improving the quality of the registration of the EUV mask 100.

FIGS. 10A and 10B are respectively a plan view and an enlarged view of the EUV mask, and FIG. 10B is an enlarged view of portion A of FIG. 10A. It will be described with reference to FIGS. 2A and 2B together.

Referring to FIGS. 10A and 10B, FIG. 10A illustrates an upper surface of the absorption layer 130 of the EUV mask 100. As described above, the absorption layer 130 may be divided into a transfer area PA and a non-transfer area NPA, and a pattern to be transferred to a wafer may be formed on the transfer area PA.

The transfer area PA of the absorption layer 130 may be divided into a two-dimensional mesh shape, as shown in the enlarged view of FIG. 10B. The size of the mesh may be set in various ways by the user. For example, one square of the mesh may have a width ranging from several hundred µm to several mm. Meanwhile, a plurality of asymmetric deformation elements ADE may be arranged within one square of the mesh. Specifically, among the three squares of the mesh illustrated in FIG. 10B, the first asymmetric deformation elements ADE1 may be arranged in a two-dimensional array structure within the square on the left, and the second asymmetric deformation elements ADE2 may be arranged in a two-dimensional array structure within the square in the center. In addition, as in the square on the right, the first asymmetric deformation elements ADE1 and the second asymmetric deformation elements ADE2 may be arranged in a complex manner within the square.

For reference, the asymmetric deformation elements ADE may be generated in the reflective multilayer 110 as described above. Accordingly, the meaning that the asymmetric deformation elements ADE are arranged within the squares of the mesh may denote that the asymmetric deformation elements ADE are generated in the lower reflective multilayer 110 corresponding to the squares of the mesh. In some implementations, the concept of a mesh may be defined on the reflective multilayer 110, and in such a case, it may be explained that the asymmetric deformation element ADE is generated within the square of the mesh.

The first asymmetric deformation element ADE1 may correspond to a vertical deformation element, and accordingly, a compressive stress may be applied in the Y-axis direction as shown by the arrow. The second asymmetric deformation element ADE2 may correspond to a horizontal deformation element, and a compressive stress may be applied in the X-axis direction as shown by the arrow.

In the case when the first asymmetric deformation element ADE1 and the second asymmetric deformation element ADE2 are arranged in a complex manner, the interior of one square of the mesh may be further divided, and the direction of the stress may be controlled. For example, within the right square, a compressive stress may be applied in the X-axis direction on both outer portions in the X-direction, and a compressive stress may be applied in the Y-axis direction on the central portion in the X-direction.

In the registration control method according to some implementations, the transfer area PA of the absorption layer 130 is divided into mesh shapes of various sizes, and horizontal and/or vertical deformation elements may be arranged in various numbers and various arrangement structures on each of the squares of the mesh. In addition, diagonal deformation elements in the 45°/-45° direction may be arranged as needed. In this way, the registration of the patterns of the absorption layer 130 may be corrected through asymmetric deformation elements arranged within each of the squares of the mesh. Therefore, the registration control method according to some implementations may very precisely correct the registration of the EUV mask 100, and accordingly, significantly improve the registration quality of the EUV mask 100.

In addition, in the case of the registration control method according to some implementations, because the laser beam L-B is applied to the reflective multilayer 110, the shot size of the laser beam or the pitch between shots may be minimized, and thus, the size of the asymmetric deformation element ADE is minimized. Accordingly, the correction resolution may be made as small as possible. For reference, when the laser beam L-B is applied to the substrate 101, if the square size of the mesh becomes fine, the shots of the laser beam L-B overlap and energy is concentrated on that part, which may cause microcracks to occur in the substrate 101. Therefore, in the case of a method of irradiating a laser beam L-B onto the substrate 101, there is a limit to the number of asymmetric deformation elements ADE that may be arranged within one square, and accordingly, there is a limit in reducing the correction resolution. However, in the registration control method according to some implementations, the laser beam L-B is applied to the reflective multilayer 110, and in the case of the reflective multilayer 110, even if energy is concentrated, cracks may not occur due to the material characteristics. Therefore, the registration control method according to some implementations may solve the above-mentioned problem and reduce the correction resolution by applying the laser beam to the reflective multilayer 110 to generate an asymmetric deformation element ADE.

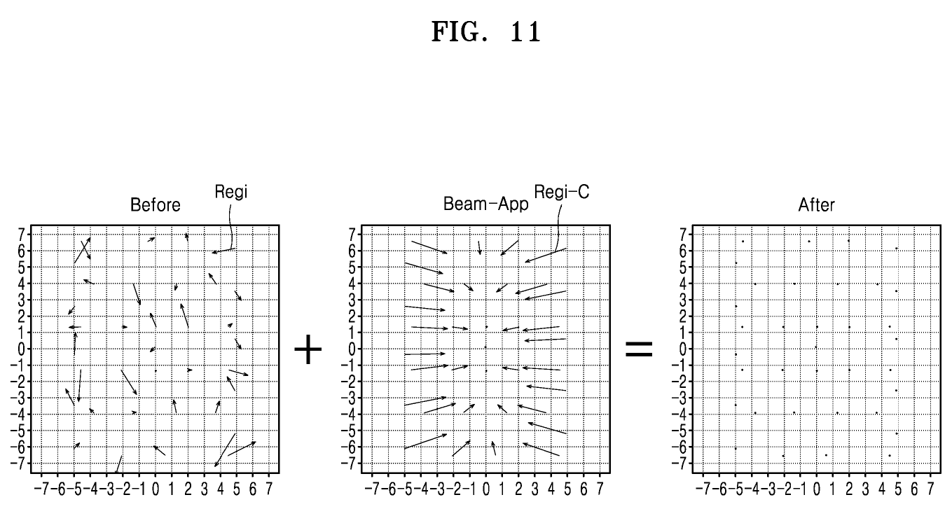

FIG. 11 is a conceptual diagram showing the principle of a method of controlling registration of an EUV mask, according to some implementations. In FIG. 11, three registration maps are illustrated, in each of the registration maps, the X-axis and the Y-axis represent position coordinates of a pattern of an absorption layer, and the unit may correspond to an arbitrary unit. It will be described with reference to FIGS. 1-2B together.

Referring to FIG. 11, among the three registration maps, the pre-correction registration map (Before) on the left may correspond to the registration map of the EUV mask 100 before registration correction is performed. The pre-correction registration map (Before) may include a registration error Regi such as the arrows illustrated.

The beam-applied registration map (Beam-App) in the center may correspond to the registration map of the EUV mask 100 including a correction registration error Regi-C. In the case of the beam-applied registration map (Beam-App), according to the registration control method of some implementations, a laser beam is applied to the reflective multilayer 110 of a normal EUV mask 100 to generate an asymmetric deformation element ADE, thereby generating a correction registration error Regi-C.

The correction registration map (After) on the right may correspond to a registration map of an EUV mask 100 that has corrected and removed the registration error Regi by generating an asymmetric deformation element capable of obtaining a beam-applied registration map (Beam-App) in the EUV mask 100 corresponding to the pre-correction registration map (Before).

For reference, the beam-applied registration map (Beam-App) in the center may correspond to a case when a correction registration error Regi-C is artificially generated by generating an asymmetric deformation element in a normal EUV mask as described above. Therefore, at first glance, it may be expected that the correction registration error Regi-C should have a form that is exact opposite form of the registration error Regi of the pre-registration map correction (Before). However, in general, because the registration error Regi of the EUV mask 100 itself and various error factors in the exposure process are combined, the correction registration error Regi-C may not have a form that is the exact opposite form of the registration error Regi.

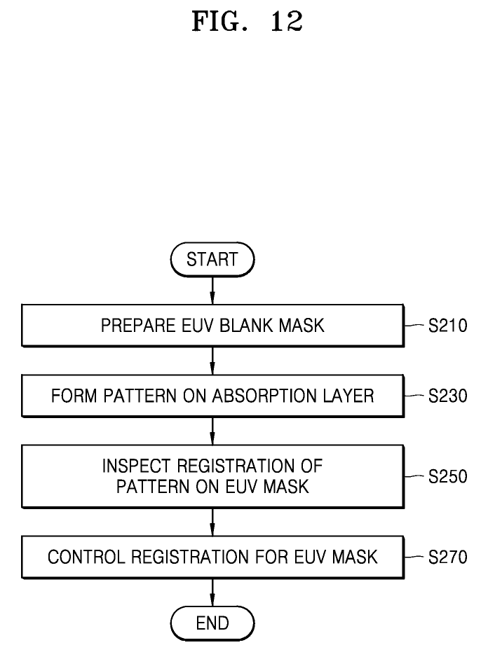

FIG. 12 is a flowchart schematically showing an EUV mask manufacturing method including a method of controlling registration of an EUV mask, according to some implementations. The EUV mask manufacturing method will be described with reference to FIGS. 1-2B together, and descriptions already given in the description of FIGS. 1-11 will be briefly described or omitted.

Referring to FIG. 12, the EUV mask manufacturing method including the registration control method of an EUV mask according to some implementations (hereinafter, simply referred to as the “EUV mask manufacturing method”) first prepares an EUV blank mask (S210). The EUV blank mask may include a substrate 101, a reflective multilayer 110, a capping layer 120, an absorption layer 130, and a rear conductive layer 140, similar to the EUV mask 100 of FIG. 2B. However, in the case of the EUV blank mask, a pattern may not be formed on the absorption layer 130.

To briefly explain the manufacturing method of the EUV blank mask, first, the reflective multilayer 110 is formed on the substrate 101. The substrate 101 may include an LTEM material. For example, the substrate 101 may include glass, Si, quartz, etc. The substrate 101 may have a larger size than the reflective multilayer 110.

The reflective multilayer 110 may have a multilayer structure in which two material layers are alternately stacked in dozens of layers. For example, the reflective multilayer 110 may include a first material layer 112 of Mo, which is a low refractive index layer, and a second material layer 114 of Si, which is a high refractive index layer. In some implementations, the first material layer 112 and the second material layer 114 may include or be composed of materials other than Mo and Si. When forming the reflective multilayer 110, the capping layer 120 may further be formed on an upper surface of the reflective multilayer 110. The capping layer 120 may be formed to prevent damage to the reflective multilayer 110 and surface oxidation of the reflective multilayer 110. For example, the capping layer 120 may include Ru. The capping layer 120 may be optional. Accordingly, in some implementations, the capping layer 120 may be omitted.

Thereafter, the absorption layer 130 is formed on the reflective multilayer 110 or the capping layer 120. That is, the absorption layer 130 may be formed on the capping layer 120, or, if the capping layer 120 is omitted, on the reflective multilayer 110. As described above, the absorption layer 130 may be divided into a central transfer area PA and an outer non-transfer area NPA. The absorption layer 130 may include a material that absorbs EUV light. For example, the absorption layer 130 may include TaN, TaHf, TaHfN, TaBSi, TaBSiN, TaB, TaBN, TaSi, TaSiN, TaGe, TaGeN, TaZr, TaZrN, or any combination thereof. In some implementations, the absorption layer 130 may include or be composed of other materials. Before forming the absorption layer 130, an EUV blank mask inspection that inspects the defects of the reflective multilayer 110 may be performed in advance.

After preparing the EUV blank mask, a pattern is formed on the absorption layer 130 (S230). Specifically, a process pattern may be formed in the non-transfer area NPA of the absorption layer 130, and a pattern may be formed in the transfer area PA. The pattern of the transfer area PA is transferred to a wafer and may be an object to registration correction.

For reference, the process pattern may denote a pattern that is essential and/or commonly formed on the EUV mask 100. The process pattern may include, for example, an inspection pattern, an alignment pattern, a measurement pattern, a monitoring pattern, an EUV scan pattern, etc. used in a manufacturing process of an EUV mask or an exposure process using an EUV mask. Specifically, the process pattern may include an alignment key, an EUV Reflectance (EUVR) measurement pad, various process/equipment monitoring keys during the manufacturing of an EUV mask, and various keys or marks used in an EUV scanner. The pattern of the transfer area PA may be formed on the transfer area PA during the process of forming the process pattern, or before or after the process of forming the process pattern.

After the formation of the pattern, the registration of the pattern on the EUV mask is inspected (S250). The registration inspection of the pattern is as described in the description part of the registration inspection operation (S110) of the registration control method of FIG. 1. After the registration inspection of the pattern, a registration map for the EUV mask 100 may be generated.

After the registration inspection, registration control for the EUV mask is performed (S270). The registration control operation (S270) may include an operation of controlling a laser beam or an E-beam (S130), an operation of generating an asymmetric deformation element (S150), and an operation of correcting the registration (S170) of the registration control method of FIG. 1.

Through the registration control operation (S270), the registration error of the EUV mask 100 is corrected, and thus, the manufacturing of the EUV mask 100 may be completed. The EUV mask manufacturing method according to some implementations may precisely correct the registration error of the absorption layer 130 by applying a laser beam or an E-beam to the reflective multilayer 110 to generate an asymmetric deformation element in the reflective multilayer 110. Accordingly, it is possible to manufacture an excellent EUV mask 100 with improved registration quality.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the inventive concept has been described with reference to the implementations shown in the drawings, it will be understood by those of ordinary skill in the art that various changes in form and details may be made therein without departing from the spirit and scope of the inventive concept. Accordingly, the scope of the inventive concept is defined not by the detailed description of the inventive concept but by the appended claims.

While the inventive concept has been particularly shown and described with reference to implementations thereof, it will be understood that various changes in form and details may be made therein without departing from the spirit and scope of the following claims.

What is claimed is:

1. A method of controlling registration of an extreme ultra-violet (EUV) mask, the method comprising:
irradiating a laser beam or an E-beam onto a reflective multilayer of the EUV mask comprising a substrate, the reflective multilayer on the substrate, and an absorption layer on the reflective multilayer;
generating an asymmetric deformation element in the reflective multilayer; and
correcting the registration of a pattern formed in the absorption layer.

2. The method of claim 1, wherein irradiating the laser beam or the E-beam comprises:
asymmetrically deforming an intensity distribution on a plane of the laser beam and irradiating the laser beam.

3. The method of claim 1, wherein irradiating the laser beam or the E-beam comprises:
asymmetrically deforming an energy distribution on a plane of the E-beam and irradiating the E-beam.

4. The method of claim 1, wherein irradiating the laser beam or the E-beam comprises:
irradiating the laser beam or the E-beam onto the reflective multilayer in an elliptical shot having an X-axis as a major axis or a Y-axis as a major axis in an X-Y plane.

5. The method of claim 4, wherein registration change is generated in a direction of the major axis based on generating compressive stress in the direction of the major axis.

6. The method of claim 1, wherein, based on a horizontal cross-section of the absorption layer being divided into a two-dimensional mesh, a plurality of asymmetric deformation elements corresponding to a shot of the laser beam or the E-beam are arranged within one square of the mesh.

7. The method of claim 1, wherein irradiating the laser beam or the E-beam comprises:
irradiating the laser beam or the E-beam onto the reflective multilayer based on the laser beam or the E-beam passing through the substrate from a rear side of the mask, or
irradiating the laser beam or E-beam onto the reflective multilayer from a front side of the mask.

8. The method of claim 1, wherein irradiating the laser beam or the E-beam comprises:
asymmetrically deforming an intensity distribution of the laser beam using an optical element and irradiating the laser beam.

9. The method of claim 1, wherein irradiating the laser beam or the E-beam comprises:
asymmetrically deforming an intensity distribution of the E-beam using an electromagnetic element and irradiating the E-beam.

10. The method of claim 1, wherein irradiating the laser beam or the E-beam comprises:
generating the asymmetric deformation element at a different location of the reflective multilayer based on irradiating the laser beam or E-beam onto the different location of the reflective multilayer based on beam scanning or moving the mask.

11. A method of controlling registration of an extreme ultra-violet (EUV) mask, the method comprising:
inspecting registration of a pattern of an absorption layer of the EUV mask comprising a substrate, a reflective multilayer on the substrate, and the absorption layer on the reflective multilayer;
irradiating a laser beam or an E-beam onto the reflective multilayer through the substrate from a rear surface of the EUV mask;
generating an asymmetric deformation element in the reflective multilayer; and
correcting the registration,
wherein irradiating the laser beam or the E-beam comprises asymmetrically deforming (i) an intensity distribution on a plane of the laser beam or (ii) an energy distribution on a plane of the E- beam.

12. The method of claim 11, wherein irradiating the laser beam or the E-beam comprises:
irradiating the laser beam or E-beam onto the reflective multilayer in an elliptical shot having an X-axis as a major axis or a Y-axis as the major axis in an X-Y plane, and
generating a change in the registration in a direction of the major axis based on generating compressive stress in the direction of the major axis.

13. The method of claim 11, wherein, based on a horizontal cross-section of the absorption layer being divided into a two-dimensional mesh, a plurality of asymmetric deformation elements corresponding to a shot of the laser beam or the E-beam are arranged within one square of the mesh.

14. The method of claim 11, wherein irradiating the laser beam or the E-beam comprises:
asymmetrically deforming the intensity distribution of the laser beam using an optical element and irradiating the laser beam.

15. The method of claim 11, wherein irradiating the laser beam or the E-beam comprises:
asymmetrically deforming the intensity distribution of the E-beam using an electromagnetic element and irradiating the E-beam.

16. A method of manufacturing an extreme ultra-violet (EUV) mask, the method comprising:
preparing an EUV blank mask comprising a substrate, a reflective multilayer on the substrate, and an absorption layer on the reflective multilayer;
forming a pattern in the absorption layer of the EUV blank mask; and
controlling registration of the pattern,
wherein controlling the registration comprises:
irradiating a laser beam or an E-beam onto the reflective multilayer,
generating an asymmetric deformation element in the reflective multilayer, and
correcting the registration.

17. The method of claim 16, wherein irradiating the laser beam or the E-beam comprises:
asymmetrically irradiating (i) an intensity distribution on a plane of the laser beam or (ii) an energy distribution on a plane of the E- beam.

18. The method of claim 16, wherein irradiating the laser beam or the E-beam comprises:
irradiating the laser beam or the E-beam onto the reflective multilayer in an elliptical shot having an X-axis as a major axis or a Y-axis as the major axis in an X-Y plane, and
generating a change in the registration in a direction of the major axis based on generating compressive stress in the direction of the major axis.

19. The method of claim 16, wherein irradiating the laser beam or the E-beam comprises:
asymmetrically deforming an intensity distribution of the laser beam using an optical element, or
asymmetrically deforming an intensity distribution of the E-beam using an electromagnetic element and irradiating the E-beam.

20. The method of claim 16, comprising:
before controlling the registration, inspecting the registration,
wherein, in controlling the registration, the registration is corrected based on a registration map generated while inspecting the registration.
